(19) United States
(12) Patent Application Publication
(10) Pub. No.: US 2008/0316695 A1
(43) Pub. Date: Dec. 25, 2008

(54) Electronic Enclosure Fastening Belt

(75) Inventors: Gregory E. Arends, Cedar Park, TX (US); Henry Edwards Mecredy, III, Austin, TX (US)

Correspondence Address: Houston IP Department;JACKSON WALKER L.L.P., 1401 McKinney St., Suite 1900, Houston, TX, 77010, US

(73) Assignee: XPLORE TECHNOLOGIES CORPORATION OF AMERICA

(21) Appl. No.: 12/134,558

(22) Filed: Jun. 6, 2008

Related U.S. Application Data
(60) Provisional application No. 60/933,549, filed on Jun. 7, 2007.
(60) Provisional application No. 60/933,629, filed on Jun. 7, 2007.
(60) Provisional application No. 60/933,935, filed on Jun. 8, 2007.

(51) Int. Cl. H05K 5/00; B23P 11/00

(52) U.S. Cl. 361/683; 361/724; 29/428

(57) ABSTRACT

Enclosures for laptops, notebooks, tablets, or other portable computers are provided, the enclosures comprising a first case having a first edge defined thereon, a second case having a second edge defined thereon, wherein said first edge of said first case and said second edge of said second case abut one another; and a belt disposed around the abutted first and second edges. The belt serves to couple the first case to the second case and in certain embodiments, provides a substantially uniform clamping force so as to compress the two cases together. In certain embodiments, advantages of the present invention include, but are not limited to, a more efficient and/or more cost-effective coupling device for electronic enclosures, a device for electronic enclosures that is easier to install and manipulate, and the ability to provide a substantially uniform clamping force across a selected joined area of an electronic enclosure.

### CROSS-REFERENCE TO RELATED APPLICATION

The present application claims priority to and the benefit of U.S. provisional patent application Ser. No. 60/933,549, filed on Jun. 7, 2007, U.S. provisional patent application Ser. No. 60/933,629, filed on Jun. 7, 2007, U.S. provisional patent application Ser. No. 60/933,935, filed on Jun. 8, 2007, which are hereby incorporated by reference.

### BACKGROUND

The present invention generally relates to devices and methods for coupling sections of electronic enclosures together through the use of a clamping belt.

Electronic enclosures are designed to isolate and protect electronic components, circuitry, and circuit boards from exposure to the environment. Typically, electronic enclosures are comprised of two or more sections, which must be joined or coupled together. In designing electronic enclosures, methods must generally be found to attach or otherwise join sections of enclosures to one another as a means of protecting and packaging electronic components, circuitry and circuit boards. Additionally, where products are designed to resist intrusion by contaminants such as water and other liquids, and dust and other particulates, a pressurized elastomeric seal is typically used, which often requires an additional compressive or clamping force beyond that required merely to hold the enclosure sections together.

Conventional methods of performing both the attachment function and if necessary, the clamping function described above, include the use of pins, screws or similar threaded fasteners distributed around the periphery of the interface between the two enclosure portions, in such a way as to draw the portions together during assembly. Typically, such fasteners are inserted in one half of an enclosure and engage either threaded bores provided in the other half of the enclosure or threaded nuts encaged by said other half of the enclosure.

One of the problems inherent with the use of prior art fasteners includes the need to individually or otherwise manipulate tighten each of the fasteners or alternatively, the need to use expensive machinery to tighten all of the screws simultaneously. Another problem with conventional screw fasteners, if sealing is required, includes the lack of the uniformity of the clamping and sealing pressure.

### SUMMARY

The present invention generally relates to devices and methods for coupling a computer case together through the use of a clamping belt.

An example of one embodiment of a computer case comprises a first enclosure having a first edge defined thereon; a second enclosure having a second edge defined thereon, wherein said first edge of said first enclosure and said second enclosure of said second case abut one another; and a belt disposed around the abutted first and second edges.

An example of another embodiment of a case for a computer comprises a first enclosure portion, said enclosure portion having a periphery and including a first flange at said periphery; a second enclosure portion, said enclosure portion having a periphery and including a second flange at said periphery, wherein said first and second flanges abut one another; and a belt disposed around the abutted first and second flanges.

An example of yet another embodiment of a computer comprises a computer case; a microprocessor disposed within said case; memory media disposed within said case; wherein said case comprises: a first portion having a first edge defined thereon; a second portion having a second edge defined thereon, wherein said first edge of said first portion and said second edge of said second portion abuts one another; and a belt disposed around the abutted first and second edges.

An example of one embodiment of a method for coupling one or more sections of a computer case together comprises providing an electronic enclosure comprising a first section having a first edge defined thereon, a second section having a second edge defined thereon; joining said first edge of said first section to said second edge of said second section so as to place said first edge adjacent to said second edge; and disposing a belt around the abutted first and second edges so as to provide a substantially uniform clamping force so as to couple said first section to said second section, thereby forming a substantially sealed enclosure around the electronics disposed therein.

The features and advantages of the present invention will be apparent to those skilled in the art. While numerous changes may be made by those skilled in the art, such changes are within the spirit of the invention.

### BRIEF DESCRIPTION OF THE DRAWINGS

A more complete understanding of the present disclosure and advantages thereof may be acquired by referring to the following description taken in conjunction with the accompanying figures, wherein:

FIG. 1 illustrates a perspective view of an example of an electronic enclosure in accordance with one embodiment of the present invention.

FIG. 2 illustrates a close-up perspective view of an example of an electronic enclosure in accordance with one embodiment of the present invention.

FIG. 3 illustrates a cross-sectional view of a portion of an electronic enclosure in accordance with one embodiment of the present invention.

FIG. 4 illustrates a perspective view of a portion of an computer case in accordance with one embodiment of the present invention.

FIG. 5 illustrates another embodiment of the invention wherein the belt of the computer case includes one or more cords embedded in the belt.

FIG. 6 illustrates another embodiment of the belt of FIG. 5.

FIG. 7 illustrates another embodiment of the belt of FIG. 5.

FIG. 8 illustrates another embodiment of the belt of FIG. 5 wherein an additional seal is integrally formed with the belt.

FIG. 9 illustrates the belt of FIG. 5 installed on a computer enclosure.

FIG. 10 illustrates another embodiment of the belt of the invention installed on a computer enclosure.

FIG. 11 illustrates another embodiment of the belt of the invention installed on a computer enclosure.

While the present invention is susceptible to various modifications and alternative forms, specific exemplary embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DESCRIPTION OF PREFERRED EMBODIMENTS

The present invention generally relates to devices and methods for coupling sections of a computer case together through the use of a clamping belt.

Generally, the present invention provides devices and methods for coupling together a plurality of sections of electronic enclosures and in particular, enclosures for laptop, notebook, tablet, and similar portable computers. Advantages of certain embodiments include, but are not limited to, a more efficient and/or more cost-effective coupling device for electronic enclosures allowing for easier assembly of the computer. Other advantages may include an easier installation and/or maintenance of coupling devices, and the ability to create a substantially uniform clamping force across a selected joined area of an electronic enclosure. Additionally, in certain embodiments, the devices and methods of the present invention provide an additional clamping force conducive to forming an effective seal in those enclosures having a compressible seal.

In this way, enclosures of the present invention provide protection and packaging for electronic components, circuitry, and circuit boards.

In certain embodiments, electronic enclosures of the present invention comprise a first case having a first edge and a second case having a second edge, the first and second edges abutting one another wherein a belt is disposed around the abutted first and second edges. Optionally, a compressible seal may be disposed between the abutted first and second edges so as to further resist intrusion by contaminants such as water and other liquids, and dust and other particulates.

To facilitate a better understanding of the present invention, the following examples of certain embodiments are given. In no way should the following examples be read to limit, or define, the scope of the invention.

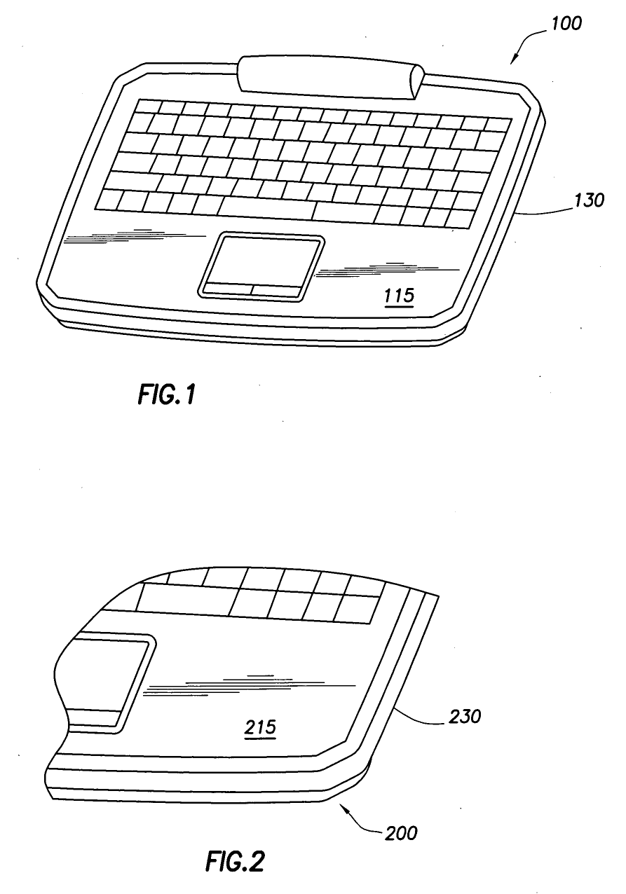

FIG. 1 illustrates a perspective view of an example of an electronic enclosure 100 in accordance with one embodiment of the present invention. Belt 130 is disposed around the periphery of computer 115, in this case, a notebook computer. Computer 115 is comprised of two sections (referred to herein as first and second sections 110, 120), which are coupled together by belt 130. Belt 130 provides a substantially uniform clamping force along substantially all of the periphery of computer 115 so as to join sections of computer 115 to one another.

Belt 130 may be fabricated out of any material suitable for coupling two sections of an electronic enclosure together wherein belt 130 is sturdy enough to withstand the environmental conditions to which electronic enclosure 100 is expected to be exposed. Suitable materials for belt 130 include, but are not limited to, polymeric materials known in the art, metals, elastomeric materials known in the art including rubber, any alloy known in the art, composite materials including woven composite materials, or any combination thereof. In one embodiment, belt 130 is elastomeric so as to permit belt 130 to readily be installed and removed as needed without affecting its compressive properties.

While belt 130 is preferably a closed-loop of a continuous surface, the invention could be practiced with an open belt. In one instance, for example, the belt may be secured on the open ends by any standard latching mechanism capable of securing the open ends. Preferably such a mechanism would further have the capability of drawing the open ends together, thereby decreasing the circumference of the belt and tightening the belt around the mated computer sections. In another embodiment of an open-loop belt, the belt may be formed of a rigid material so as to essentially form an elongated clamp. That is, a more rigid belt may have the shape of the belt illustrated in FIG. 7. In such case, the “belt” of the invention may have limited flexibility and be more akin to an elongated clamp that is placed around the periphery of a computer enclosure.

FIG. 2 illustrates a close-up perspective view of an example of an electronic enclosure 200 in accordance with one embodiment of the present invention. Here, as before, belt 230 couples sections of computer 215 together.

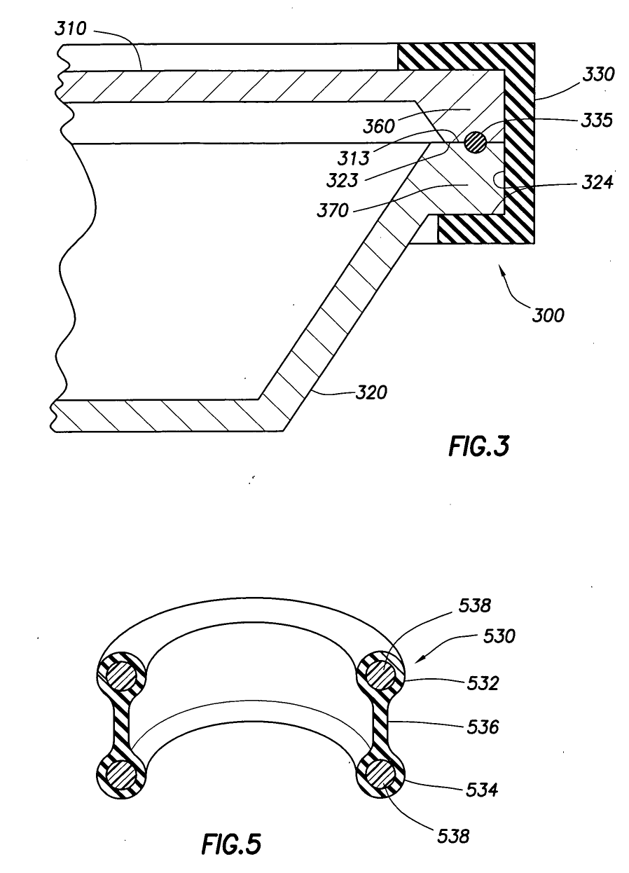

FIG. 3 illustrates a cross-sectional view of a portion of an electronic enclosure 300 in accordance with one embodiment of the present invention. Electronic enclosure 300 is comprised of first section 310, second section 320, belt 330, and compressible seal 335.

First section 310 has a first edge wherein the first edge is formed of outer surface 314 and an inner surface 313. Second section 320 has a first edge wherein the first edge is formed of outer surface 324 and an inner surface 323. Inner surface 313 abuts against inner surface 323.

Belt 330, when disposed around the first and second edges of electronic enclosure 300, provides a substantially uniform clamping or compressive force around the periphery of enclosure 300 so as to couple first section 310 and second section 320 together.

Compressible seal 335 is disposed between inner surface 313 and inner surface 323. Compressible seal 335 may be formed of any material suitable for resisting intrusion by contaminants, such as water, other liquids, dust, or other particulates, and suitable for placement between first and second sections 310, 320. Suitable compressible seals include, but are not limited to, elastomeric seals, polymeric seals, gaskets, or any combination thereof.

Flange 360 is the region of first section 310 that is circumscribed, at least partially, by inner surface 313 and outer surface 314. Likewise, flange 370 is the region of second section 320 that is circumscribed, at least partially, by inner surface 323 and outer surface 324. Flanges 360, 370 are adapted to interact with belt 330 and abut or otherwise mate with one another. Although belt 330 is depicted here as fully circumscribing flanges 360, 370, it is recognized that, in certain embodiments that belt 330 may be disposed around only a portion of flanges 360, 370.

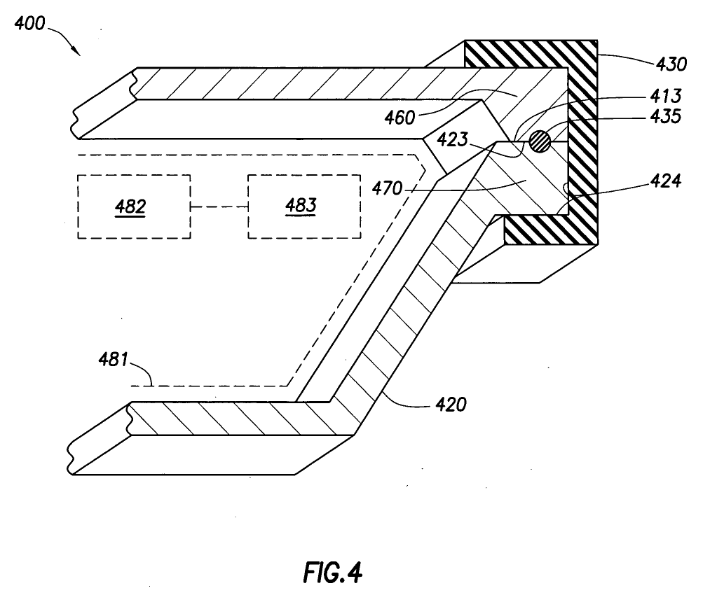

FIG. 4 illustrates a perspective view of a portion of a computer 415 in accordance with one embodiment of the present invention. Computer enclosure 400 is comprised of first section 410, second section 420, belt 430, and compressible seal 435. Illustrated within computer enclosure 400 is electronic circuitry components 481, shown here schematically. Electronic circuitry components 481 further comprise a microprocessor 482 and memory media 483 among other components not shown. Computer enclosure 400 along with electronic circuitry components 481 form computer 415.

Similar to the embodiment depicted in FIG. 3, first section 410 has a first edge wherein the first edge is formed of outer surface 414 and an inner surface 413. Second section 420 has a first edge wherein the first edge is formed of outer surface 424 and an inner surface 423. Inner surface 413 abuts against inner surface 423.

Belt 430 is disposed around the first and second edges of computer enclosure 400 and extends around the periphery of first and second sections 410, 420 so as to secure the coupled first section 410 and second section 420 together.

Compressible seal 435 is disposed between inner surface 413 and inner surface 423. A recess or recesses may be provided in first section 410 and/or second section 420 to provide a depression in which compressible seal 435 may be seated.

As before, although belt 430 is depicted here as fully circumscribing flanges 460, 470, it is recognized that, in certain embodiments that belt 430 may be disposed around only a portion of flanges 460, 470.

Likewise, belt 430 may be disposed around only a portion of the periphery of enclosure 400.

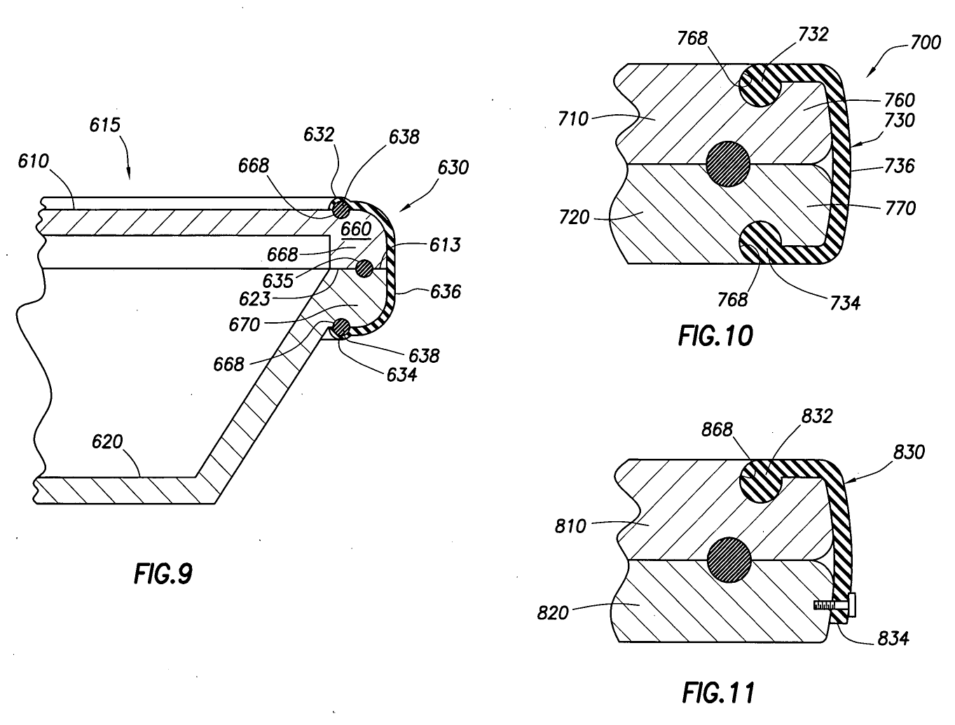

Turning to FIG. 5, another embodiment of the invention is depicted wherein the above described belt 130 has one or more cords imbedded therein. More specifically there is shown a belt 530 formed of elastomeric material and having a first edge 532 and a second edge 534 with a web 536 formed therebetween. Embedded at each edge is a cord 538. Cord 538 may be formed of any material capable of providing tensile reinforcement to the belt 538, some non-limiting examples including textile cord or aramid fiber cord (or aramid cord), in the case of the latter, at least one of the cord fibers, or threads, is an aramid (i.e., a highly aromatic polyamide). Preferably, belt 530 is a closed-loop or continuous belt, although the invention could be practiced with an open belt that may be secured on the open ends by any standard latching mechanism capable of securing the open ends. Preferably such a mechanism would further have the capability of drawing the open ends together, thereby decreasing the circumference of the belt and tightening the belt around sections 610, 620 of computer 615 (see FIG. 9). With reference to FIG. 9, it will be appreciated that when belt 630 is installed around the periphery of computer 615, belt 630 forms a seal over the adjacent sections 610, 620, thereby providing a seal in addition to any o-ring that may be disposed between the adjacent sections.

In any event, in the preferred embodiment of FIG. 5, edges 532, 534 are rounded and formed about cord 530, while web 536 has a narrower profile. Those skilled in the art will appreciate that the particular shape of cord 538, edges 532, 534 and belt 530 should not be construed as limiting so long as an elastomeric belt 530 with at least one cord 538 embedded therein is provided.

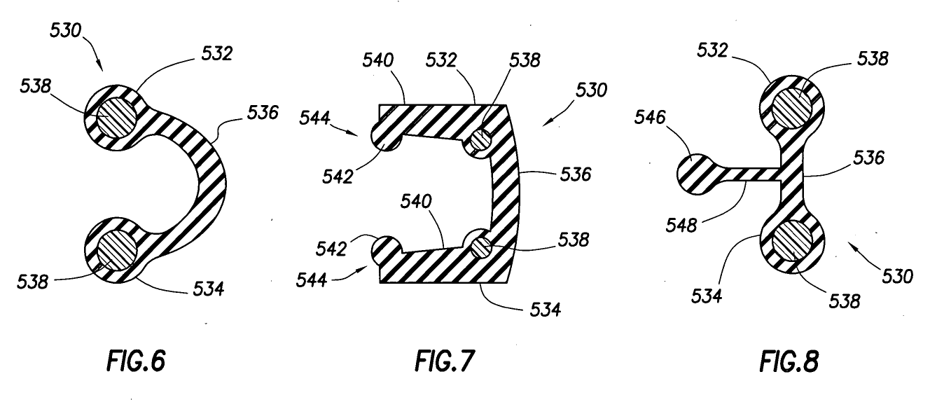

FIGS. 6 and 7 illustrate other embodiments of a belt 530 with a cord 538 embedded therein. In FIG. 6, the web 536 of belt 530 is curved so as to form a “C” shape. In FIG. 7, belt 530 includes additional belt flanges 540 extending out from the embedded cords 538. Flanges 540 include an additional lip 542 at their distal end 544, which lip can seat in the groove of a computer case to further seat belt 530 around computer 115.

FIG. 8 illustrates an embodiment of belt 530 where an additional sealing o-ring 546 is integrally formed as part of belt 530. In this case, o-ring 546 is carried on a flange 548 extending out from web 536.

FIG. 9 illustrates a belt of the invention installed around the periphery of computer 615 formed of first and second sections as generally described herein. Specifically there is shown an enclosure 600 formed of first and second sections 610, 620 which are secured to one another by belt 630.

Belt 630 is formed of elastomeric material and has a first edge 632 and a second edge 634 with a web 636 formed therebetween. Embedded at each edge is a cord 638.

First section 610 has a first edge wherein the first edge is formed of outer surface 614 and an inner surface 613. Second section 620 has a first edge wherein the first edge is formed of outer surface 624 and an inner surface 623. Inner surface 613 abuts inner surface 623.

Flange 660 is the region of first section 610 that is circumscribed, at least partially, by inner surface 613 and outer surface 614. Likewise, flange 670 is the region of second section 620 that is circumscribed, at least partially, by inner surface 623 and outer surface 624. Flanges 660, 670 are adapted to interact with belt 630 and abut or otherwise mate with one another. In this regard, each section 610, 620 is provided with a groove or recess 668 in its respective outer surfaces 614, 624. Belt 630 is disposed around flanges 660, 670 so that first edge 632 of belt 630 seats in the recess 668 of section 610 while second edge 634 seats in the recess 668 of section 620.

Belt 630, when disposed around the first and second edges of electronic enclosure 600, provides a substantially uniform clamping or compressive force around the periphery of enclosure 600 so as to couple first section 610 and second section 620 together. Moreover, belt 630, being formed of a material capable of sealing, forms a seal around the joined flanges 660, 670, thereby minimizing migration of fluid or debris into the interior of computer enclosure 615.

Compressible seal 635 may be provided to further enhance the sealing of computer enclosure 615 as described above.

FIGS. 10 and 11 illustrate additional embodiments of the invention wherein the belt of the invention is elastomeric. In FIG. 10, a belt 730 is shown disposed around first and second sections 710, 720 of enclosure 700. In this embodiment, belt 730 is formed of elastomeric material and has a first edge 732 and a second edge 734 with a web 736 formed therebetween. Each of edges 732, 734 are enlarged in shape relative to web 736. Specifically, the cross sectional thickness of edges 732, 734 is larger than the cross-sectional thickness of web 736. While the enlarged shape of edges 732, 734 are shown as being substantially round, those skilled in the art will appreciate that enlarged edges 732, 734 can have any shape so long as they function as described herein.

Edges 732, 734 are shaped so as to seat within recesses 768 provided in sections 710, 720. Recesses 768 are formed in sections 710, 720 so as to have an opening 762 that is smaller than the cross-section of the belt edges such that a belt edge can pass through opening 762 only upon compression of the belt edge. Once the compressed edge has passed through opening 762, the belt edge can expand to fill recess 768. In this way, each belt edge 732, 734 is secured by its respective recess 768. When belt 730 is disposed around flanges 760, 770, then sections 710, 720 are secured together.

FIG. 11 illustrates another embodiment of the invention shown in FIG. 11. In the embodiment of FIG. 11, however, only one edge 832 of belt 830 is enlarged, as described above, and seats in a recess 868 of section 810. The opposite edge 834 is simply attached to its respective section 820 utilizing any standard attachment device, including without limitation, fasteners or adhesives.

It is explicitly recognized that while the belts of the invention have been described primarily in the context of computer enclosures, the belt may also be used for other types of electronic component enclosures.

Furthermore, the invention is particularly desirable for use with computer systems designed to facilitate an expedited assembly, such as multi-configurable systems or systems that minimize the use of prior art fasteners. For example, to expedite computer assembly, a multiple-configurable portable computer has been developed that utilizes a “universal” lower housing having a main logic board and a configuration module connector disposed therein. This allows the universal base to be readily attached to an upper housing pre-configured to be any of (a) a tablet display; (b) a notebook computer keyboard and notebook display; or (c) a convertible display having a keyboard and a convertible display. Preferably, the configuration module connector is adapted to interface and communicate with a configuration module carried by the respective housing, such that only a single electrical connection need be made between the lower housing and upper housing. In other words, the lower housing and the configuration module connector allow for interchangeability of (a), (b), or (c). In one embodiment, the configuration module connector is structurally mounted on the main logic board. In any event, once a upper housing is engaged with the lower housing and the electrical connection has been made, the belt of the invention permits the two housings to be quickly secured to one another without the need for traditional prior art fasteners. Thus, a computer system could literally be manufactured in seconds.

Any of the features and components disclosed in Applicant's concurrently filed non-provisional patent applications may be used in conjunction with embodiments of the present invention, namely U.S. patent application Ser. No. ______, entitled “Elastomeric Enclosure Having Electronic Circuit Board Standoffs” (which claims priority to U.S. Provisional Application Ser. No. 60/933,935) and U.S. patent application Ser. No. ______, entitled “Configurable Computer System and Methods of Use” (which claims priority to U.S. provisional Application Ser. No. 60/933,629), the specifications of which are hereby incorporated by reference. In particular, it is explicitly recognized that embodiments described in these concurrently-filed specifications may be used in conjunction with the embodiments herein to eliminate traditional fasteners.

Therefore, the present invention is well adapted to attain the ends and advantages mentioned as well as those that are inherent therein. The particular embodiments disclosed above are illustrative only, as the present invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered or modified and all such variations are considered within the scope and spirit of the present invention. Also, the terms in the claims have their plain, ordinary meaning unless otherwise explicitly and clearly defined by the patentee.

What is claimed is:

1. An enclosure for an electronic device, said enclosure comprising:
a first case having a first edge defined thereon;
a second case having a second edge defined thereon, wherein said first edge of said first case and said second edge of said second case abut one another; and
a belt disposed around the abutted first and second edges.

2. The enclosure of claim 1, wherein said first edge is defined by at least one outer surface and an inner surface and wherein said second edge is defined by at least one outer surface and an inner surface, and wherein the inner surfaces of the first and second cases abut one another and the belt is disposed around said outer surfaces.

3. The enclosure of claim 2, further comprising a compressible seal disposed between said abutting inner surfaces.

4. The enclosure of claim 3, wherein said compressible seal is an o-ring or a gasket.

5. The enclosure of claim 4, wherein said compressible seal is formed of an elastomeric material.

6. The enclosure of claim 1, wherein each case is defined by a periphery and each edge circumscribes the entire periphery of said case, wherein said edges abut one another around the entire periphery of each case.

7. The enclosure of claim 1, wherein said belt comprises an elastomeric material with at least one elongated cord embedded in a portion of the belt.

8. The enclosure of claim 7, wherein said belt comprises at least two cords, wherein the belt is characterized by a first edge and a second edge and a web formed therebetween, wherein a cord is embedded in each edge.

9. The enclosure of claim 7, wherein said cord is an aramid fiber cord.

10. The enclosure of claim 7, wherein at least one case edge has a recess defined therein and said belt is disposed around the edge so that the portion of the belt in which the cord is embedded seats in the recess.

11. The enclosure of claim 7, wherein said belt comprises a first edge and a second edge and a web formed therebetween, with a cord embedded in each of said edges, and wherein each case edge has a recess defined therein and said belt is disposed around the first and second edges so that the portion of the belt in which the cords are embedded seat in their respective recesses.

12. The enclosure of claim 1, wherein said belt is formed of an elastomeric material and comprises a first enlarged edge and a second enlarged edge, said enlarged edges having a cross-sectional area, and a web formed between said enlarged edges, said web having a cross-sectional area smaller than said enlarged edge cross sectional area, and wherein each case edge has a recess defined therein and said belt is disposed around the first and second edges so that an enlarged edge of said belt seats within the recess of each case.

13. The enclosure of claim 12, wherein said recess comprises a hollow formed in the case and includes an opening into said hollow, said opening defined by a cross-sectional area that is smaller than the cross-sectional area of the enlarged edge cross sectional area.

14. A case for a computer, said case comprising:
a first enclosure portion, said enclosure portion having a periphery and including a first flange at said periphery;
a second enclosure portion, said enclosure portion having a periphery and including a second flange at said periphery, wherein said first and second flanges abut one another; and
a belt disposed around the abutted first and second flanges.

15. The computer case of claim 14, wherein each of said flanges protrude from said enclosure portion and wherein said first flange is defined by at least one outer surface and an inner surface and wherein said second flange is defined by at least one outer surface and an inner surface, and wherein the inner surfaces of the first and second flanges abut one another to form an overall protruding flange for the case and the belt is disposed around said overall protruding flange.

16. The computer case of claim 14, further comprising a recess in at least one of said flanges and compressible seal disposed in said recess wherein said compressible seal is an o-ring.

17. The enclosure of claim 14, wherein said belt comprises an elastomeric material with at least one elongated cord embedded in a portion of the belt.

18. The enclosure of claim 17, wherein said belt comprises at least two cords, wherein the belt is characterized by a first edge and a second edge and a web formed therebetween, wherein a cord is embedded in each edge.

19. The enclosure of claim 17, wherein said cord is an aramid fiber cord.

20. The enclosure of claim 17, wherein at least one case edge has a recess defined therein and said belt is disposed around the edge so that the portion of the belt in which the cord is embedded seats in the recess.

21. The enclosure of claim 17, wherein said belt comprises a first edge and a second edge and a web formed therebetween, with a cord embedded in each of said edges, and wherein each case edge has a recess defined therein and said belt is disposed around the first and second edges so that the portion of the belt in which the cords are embedded seat in their respective recesses.

22. The enclosure of claim 14, wherein said belt is formed of an elastomeric material and comprises a first enlarged edge and a second enlarged edge, said enlarged edges having a cross-sectional area, and a web formed between said enlarged edges, said web having a cross-sectional area smaller than said enlarged edge cross sectional area, and wherein each case edge has a recess defined therein and said belt is disposed around the first and second edges so that an enlarged edge of said belt seats within the recess of each case.

23. The enclosure of claim 22, wherein said recess comprises a hollow formed in the case and includes an opening into said hollow, said opening defined by a cross-sectional area that is smaller than the cross-sectional area of the enlarged edge cross sectional area.

24. A computer, said computer comprising:
a computer case;
a microprocessor disposed within said case;
memory media disposed within said case;
wherein said case comprises:
a first portion having a first edge defined thereon;
a second portion having a second edge defined thereon, wherein said first edge of said first portion and said second edge of said second portion abuts one another; and
a belt disposed around the abutted first and second edges.

25. The computer of claim 24, wherein said first edge is defined by at least one outer surface and an inner surface and wherein said second edge is defined by at least one outer surface and an inner surface, and wherein the inner surfaces of the first and second portions abut one another and the belt is disposed around said outer surfaces.

26. The computer of claim 25, further comprising a compressible seal disposed between said abutting inner surfaces, wherein said belt is disposed around the first and second edges wherein said belt is adapted to exert a clamping force on said edges so as to activate said compressible seal.

27. The computer of claim 26, wherein said compressible seal comprises an o-ring and wherein said o-ring comprises an elastomeric material.

28. The enclosure of claim 24, wherein said belt comprises an elastomeric material with at least one elongated cord embedded in a portion of the belt.

29. The enclosure of claim 28, wherein said belt comprises at least two cords, wherein the belt is characterized by a first edge and a second edge and a web formed therebetween, wherein a cord is embedded in each edge.

30. The enclosure of claim 28, wherein said cord is an aramid fiber cord.

31. The enclosure of claim 28, wherein at least one case edge has a recess defined therein and said belt is disposed around the edge so that the portion of the belt in which the cord is embedded seats in the recess.

32. The enclosure of claim 28, wherein said belt comprises a first edge and a second edge and a web formed therebetween, with a cord embedded in each of said edges, and wherein each case edge has a recess defined therein and said belt is disposed around the first and second edges so that the portion of the belt in which the cords are embedded seat in their respective recesses.

33. The enclosure of claim 24, wherein said belt is formed of an elastomeric material and comprises a first enlarged edge and a second enlarged edge, said enlarged edges having a cross-sectional area, and a web formed between said enlarged edges, said web having a cross-sectional area smaller than said enlarged edge cross sectional area, and wherein each case edge has a recess defined therein and said belt is disposed around the first and second edges so that an enlarged edge of said belt seats within the recess of each case.

34. The enclosure of claim 33, wherein said recess comprises a hollow formed in the case and includes an opening into said hollow, said opening defined by a cross-sectional area that is smaller than the cross-sectional area of the enlarged edge cross sectional area.

35. A method for coupling one or more sections of an electronic enclosure together comprising:
providing an electronic enclosure comprising a first case having a first edge defined thereon, a second case having a second edge defined thereon;
joining said first edge of said first case to said second edge of said second case so as to place said first edge adjacent to said second edge; and
disposing a belt around the abutted first and second edges so as to provide a substantially uniform clamping force so as to couple said first case to said second case.

36. The method of claim 35 further comprising disposing a compressible seal between the first edge and the second edge before disposing a belt around the abutted first and second edges.
